(19) United States
(12) Patent Application Publication
(10) Pub. No.: US 2005/0189218 A1
(43) Pub. Date: Sep. 1, 2005

(54) Cathodic arc coating apparatus

(76) Inventors: Tao Qian, Singapore (SG); Xin Ge, Singapore (SG)

Correspondence Address: JOEL D. SKINNER, JR.;SKINNER AND ASSOCIATES, 212 COMMERCIAL ST., HUDSON, WI, 54016, US

(21) Appl. No.: 11/041,789

(22) Filed: Jan. 24, 2005

(30) Foreign Application Priority Data
Feb. 27, 2004 (SG) 200401494-0

(51) Int. Cl. C23C 14/34

(52) U.S. Cl. 204/298.41; 204/192.38

(57) ABSTRACT

A cathodic arc coating apparatus (2) includes an elongated hollow cathode (10), elongated magnetic field means (12) located coaxially within the cathode, and elongated cooling supply passages located coaxially within the cathode for directly cooling the cathode. In a preferred arrangement the magnetic field means is hollow and the cooling means includes elongated passage means extending coaxially and within the magnetic field means. The cathode means may be rotated. In use, a closed loop arc path is formed which extends along substantially the full length of the cathode.

### TECHNICAL FIELD

This invention relates to cathodic arc coating apparatus, and in particular to cathodic arc coating apparatus incorporating an elongated hollow cathode.

### BACKGROUND ART

The deposit of material from a cathode onto a substrate article by the use of an electric arc is well known. The process is conducted in a vacuum chamber which can act as the anode, and the electric arc causes vaporisation/ionisation of the cathode material to be deposited. The particles evaporated are subsequently deposited on the substrate article to form a coating of the material from the cathode.

Elongated cathodes are also well known. For example, in patent specification U.S. Pat. No. 5,269,898, there is disclosed an elongated rod shaped cathode/target mounted within a vacuum chamber, and the cathode rod is coaxially surrounded by a helical magnetic coil for the purpose of forcing the motion of the arc into an open helical trajectory on the cathode surface.

Problems faced by known cathodic arc apparatus include the ability to obtain acceptable uniform controlled erosion of material from the cathode/target, and also to obtain uniform controlled deposit of a coating finish on the substrate article.

It is an object of the present invention to provide coating apparatus which will result in acceptable erosion and deposit standards and thereby provide a useful alternative to known cathodic arc coating apparatus.

### DISCLOSURE OF INVENTION

According to the invention, there is provided a cathodic arc coating apparatus including an elongated hollow cathode, elongated magnetic field means located co-axially and substantially within the cathode, and elongated cooling supply passages located coaxially and substantially within the cathode for directly cooling the cathode.

Means may be included to rotate the cathode.

In a preferred example, the magnetic field means includes magnet bars of different lengths along its longitudinal axis. Preferably, in use, the magnetic field means causes an elongated closed loop arc path to be formed, which extends along substantially the full length of the cathode. Means may be provided to adjust the strength and direction of the magnetic field.

The cooling supply means preferably include a central longitudinal passage extending along and within the magnetic means longitudinal axis, and connecting with further passage means to feed the cooling medium onto the inner face of the hollow cathode.

The cathode may be formed of any suitable material or materials. For example, it may be formed of two different materials, such as an inner elongated copper tube and an outer elongated chromium target tube, bonded together using known bonding methods.

The hollow/tubular components of the apparatus may be of any suitable size or cross-section.

According to another aspect of the invention there is provided cathodic arc coating apparatus adapted to be connected to a bore through a vacuum chamber wall by coupling means, the coupling means being adapted to be electrically insulated from the chamber wall and to be pressure sealed from the vacuum chamber;
an inner part of the cathodic arc coating apparatus adapted to extend within the vacuum chamber and including an elongated hollow cathode which houses co-axial elongated hollow magnetic field means;
an outer part of the cathodic arc coating apparatus is adapted to extend outside the vacuum chamber and includes a hollow rotatable shaft for rotating the cathode/target, and which houses a co-axial magnetic means fixed hollow support shaft, and
cooling passage means including a central longitudinal passage extending within and along the magnetic means support shaft and magnetic means longitudinal axes, and
said longitudinal cooling passage means connecting with further passage means to facilitate the feeding of the cooling medium along the inner face of the hollow cathode.

### BRIEF DESCRIPTION OF THE DRAWINGS

FIG. 1 is a part sectional front view of an embodiment of a cathodic arc coating apparatus constructed in accordance with the invention, wherein the cathode/target is adapted for rotation.

FIG. 2 is a part sectional view of the cathode sub-assembly of FIG. 1.

FIG. 3 is a part sectional side view of the magnet sub-assembly assembly of FIG. 1.

FIG. 4 is a part side view of the magnetic assembly of FIG. 3.

FIG. 5 is an enlarged part cross sectional view taken along the lines AA of FIG. 4.

FIG. 6 is a partial side view of FIG. 1 showing the arc path in dotted outline.

FIG. 7 is a sectional view of an alternative cathode formed of two different materials.

### BEST MODE OF CARRYING OUT THE INVENTION

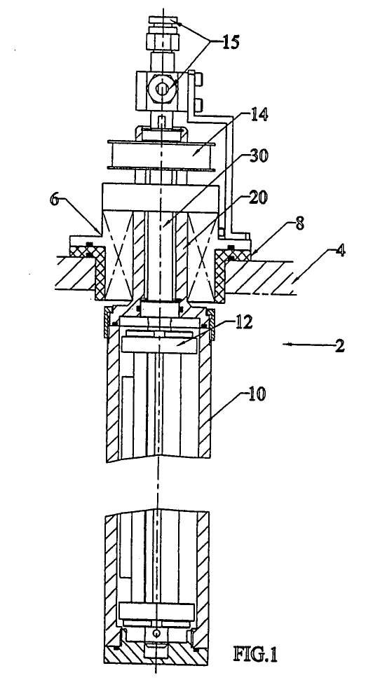

Referring first to FIG. 1, there is shown an embodiment of the invention in which the cathode/target is adapted for rotation. A cathodic arc coating apparatus 2 is connected to a bore in a vacuum chamber wall 4 by a flanged cylindrical coupling member 6. The coupling member 6 is electrically insulated from the chamber wall 4 and pressure sealed from the vacuum chamber by a cylindrical flanged seal 8, while the target is rotating. The lower part of the apparatus 2 extends within the vacuum chamber and includes an elongated cathode sub-assembly 10 which houses a co-axial magnetic field generating sub-assembly 12. The upper or outer part of the apparatus 2 extends outside the vacuum chamber and includes a rotating mechanism 14 for rotating the cathode, and cooling water supply means 15 for cooling the cathode assembly. A DC electrical supply is fed into the apparatus via an electrical rotary connector assembly adjacent the rotating mechanism 14.

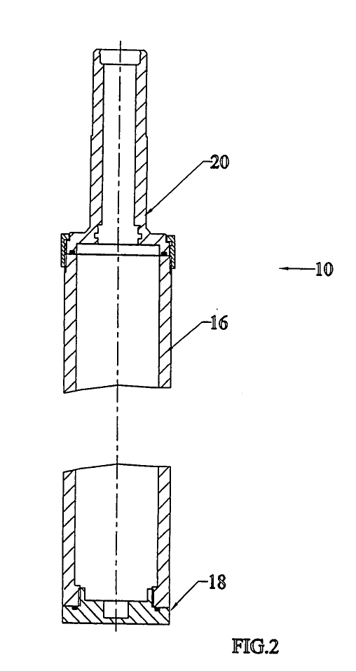

As best seen in FIG. 2 the cathode sub-assembly 10 includes an elongated hollow cylindrical cathode/target 16 sealed at its lower end by an end cap 18 and sealed and attached at its upper end to a hollow cathode drive shaft 20 adapted to be rotated by rotating mechanism 14. In preferred examples, the cylindrical cathode tube has dimensions of an outer diameter of 60 mm to 120 mm and a wall thickness of 6 mm to 12 mm.

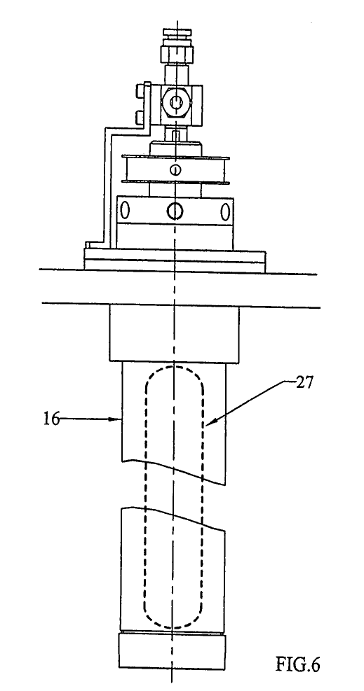

As best seen in FIGS. 1, 3, 4 and 5 the magnet sub-assembly includes a hollow magnet mounting tube 22. The hollow mounting tube 22 is coaxial with and located centrally within the hollow cylindrical cathode/target 16. A series of 3 sets of magnet bars 26 and 28 are mounted on the mounting tube 22 to form closed loop magnetic tracks along the cathode axis. Each set is equally spaced radially around the magnet mounting tube as shown in FIG. 5. Magnet bar 26 is the shorter and has open ends. Magnet bar 28 is the longer and is connected at its two ends to magnet rings 29. This arrangement facilitates, in use, an elongated closed loop arc path extending along substantially the full length of the cathode, as illustrated by dotted outline 27 in FIG. 6.

The magnet bars are provided with a waterproof plastic covering to protect them from the cooling water.

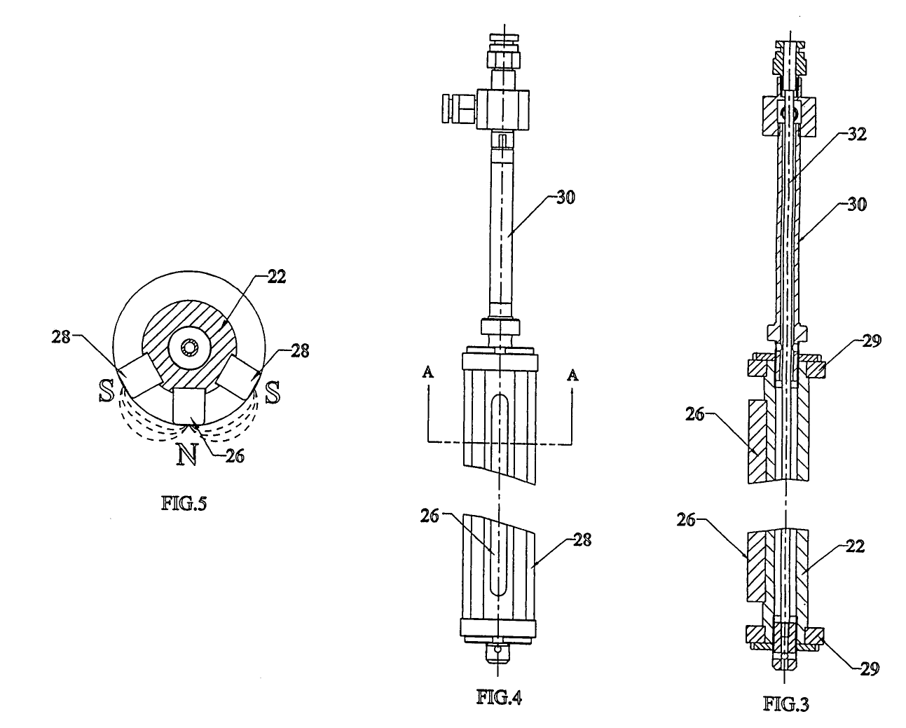

Referring to FIGS. 3 and 4, the upper end of the magnet mounting tube 22 is connected to, and supported by a co-extensive fixed magnet support tube 30. The support tube 30 extends upwardly through, and co-axially with, the cathode rotary drive shaft 20. Located coaxially within the magnet support tube 30 is a cooling water pipe 32. In operation, the cooling water is directly applied to the cathode by flowing from supply inlet 15 (See FIG. 1), through the gap between the hollow cathode drive shaft 20 and the magnet support tube 30, down the inner wall of the cathode 10, and then returns upwardly through cooling pipe 32 (FIG. 3).

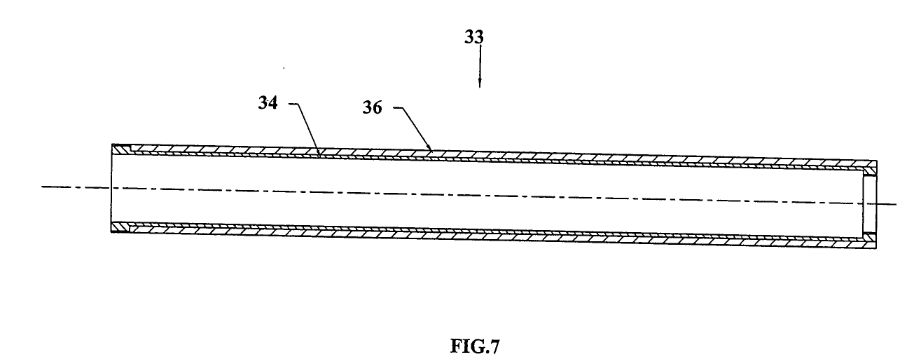

Referring to FIG. 7 an alternative elongated cathode 33 is formed of inner and outer elongated tubes 34 and 36 of different materials bonded by using known bonding methods. The inner tube 34 is formed of copper or other material having good heat conductivity. The outer tube 36 is formed of the target material such as chromium. The bonded target assembly is fully compatible with the mono material target 16 of FIG. 2.

When utilising the rotating cathode embodiment, the plasma may travel in one direction, and this enables the cathode to be located adjacent a chamber wall. Whereas in many prior art devices, the elongated cathode must be located centrally of the chamber.

In many prior art arrangements, in order to achieve large coating area for mass production, it is necessary to use multiple cathodes/targets, whereas utilising the apparatus of the embodiments of the present invention it may only be necessary to utilise one cathode/target. Thus making cost savings.

It will be appreciated that various changes can be made to the above examples by a person skilled in the art without departing from the broad concepts of the invention as defined in the following claims.

1. Cathodic arc coating apparatus including an elongated hollow cathode, elongated magnetic field means located co-axially and substantially within the cathode, and elongated cooling supply passages located coaxially and substantially within the cathode for directly cooling the cathode.

2. Cathodic arc coating apparatus according to claim 1 including means to rotate the cathode/target.

3. Cathodic arc coating apparatus according to claim 2 wherein the cathode is formed of inner and outer elongated tubes of different materials.

4. Cathodic arc coating apparatus according to claim 1 wherein, in use, the magnetic field causes a closed loop arc path to be formed which extends along substantially the full length of the cathode.

5. Cathodic arc coating apparatus according to claim 4 wherein the magnetic field means include a series of magnet bars placed along its longitudinal axis.

6. Cathodic arc coating apparatus according claim 1 wherein the cooling supply passages include a central longitudinal passage extending along and within the magnetic means longitudinal axis, and connecting with further passage means to feed the cooling medium onto the inner face of the hollow cathode.

7. Cathodic arc coating apparatus according to claim 6 wherein the central longitudinal cooling passage is located within the magnetic field means.

8. Cathodic arc coating apparatus adapted to be connected to a bore in a vacuum chamber wall by coupling means, the coupling means being adapted to be electrically insulated from the chamber wall and to be pressure sealed from the vacuum chamber;
an inner part of the cathodic arc coating apparatus adapted to extend within the vacuum chamber and including an elongated hollow cathode which houses a co-axial elongated hollow magnetic field means;
an outer part of the cathodic arc coating apparatus adapted to extend outside the vacuum chamber and including a hollow rotatable shaft for rotating the cathode, and which houses a co-axial magnetic means fixed hollow support shaft, and cooling passage means including a central longitudinal passage extending within and along the magnetic means support shaft and magnetic means longitudinal axes, and
said longitudinal cooling passage means connecting with further passage means to facilitate the feeding of cooling medium along the inner face of the hollow cathode.

9. Cathodic arc coating apparatus according to claim 8 wherein, in use, the magnetic field causes a closed loop arc path to be formed which extends along substantially the full length of the cathode.

10. Cathodic arc coating apparatus substantially as hereinbefore described with reference to FIG. 1 of the accompanying drawings.
